(19) United States
(12) Patent Application Publication
(10) Pub. No.: US 2013/0170143 A1
(43) Pub. Date: Jul. 4, 2013

(54) HEAT SINK MECHANSIM AND ELECTRONIC DEVICE USING THE SAME

(71) Applicant: XIAO-HUI ZHOU, Shenzhen City (CN)

(72) Inventor: XIAO-HUI ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/597,287

(22) Filed: Aug. 29, 2012

(30) Foreign Application Priority Data
Dec. 30, 2011 (CN) 201110452462.3

(51) Int. Cl. H05K 7/20

(52) U.S. Cl. 361/704

(57) ABSTRACT

An electronic device includes an electronic component and a heat sink mechanism. The heat sink mechanism includes a first heat sink component and a second heat sink component arranged on opposite surfaces of the electronic component. The first heat sink component includes a first conduction portion and a second conduction portion extending from the first conduction portion. The first conducting portion is secured to the electronic component, and the second conducting portion is secured to the second heat sink component, for dissipating the heat produced by the electronic component away from the electronic device.

### BACKGROUND

1. Technical Field

The present disclosure relates to a heat sink mechanism, and particularly to an electronic device having the heat sink mechanism.

2. Description of Related Art

Electronic devices, such as disc players and notebook computers, include electronic components which may generate high temperature during operation. However, each electronic device has a maximum operating temperature. If an electronic component of the electronic device operates at a temperature that exceeds the maximum operating temperature, its lifetime will be shortened and the electronic device may be damaged.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an embodiment of an electronic device.

FIG. 2 is a partial, exploded view of the electronic device of FIG. 1.

FIG. 3 is a partial, assembled view of the electronic device of FIG. 2.

### DETAILED DESCRIPTION

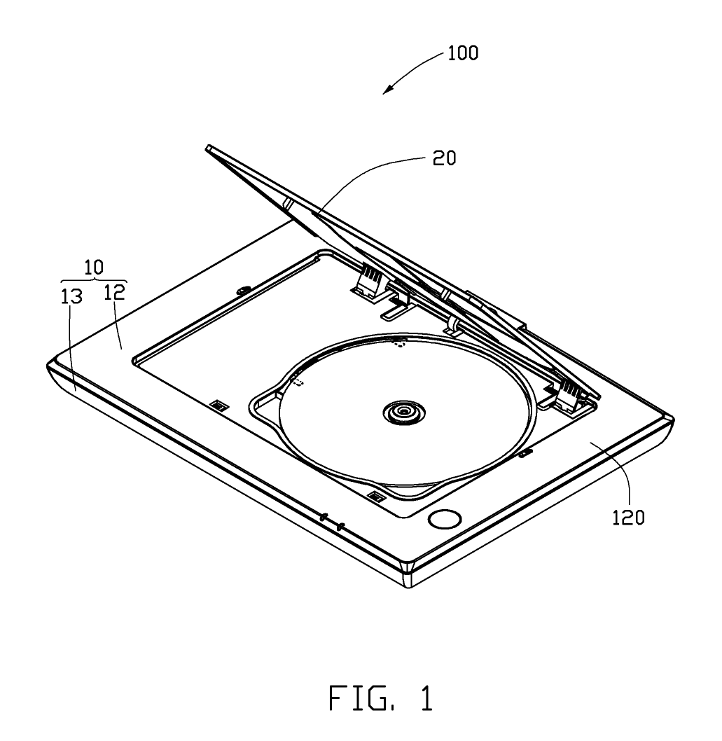

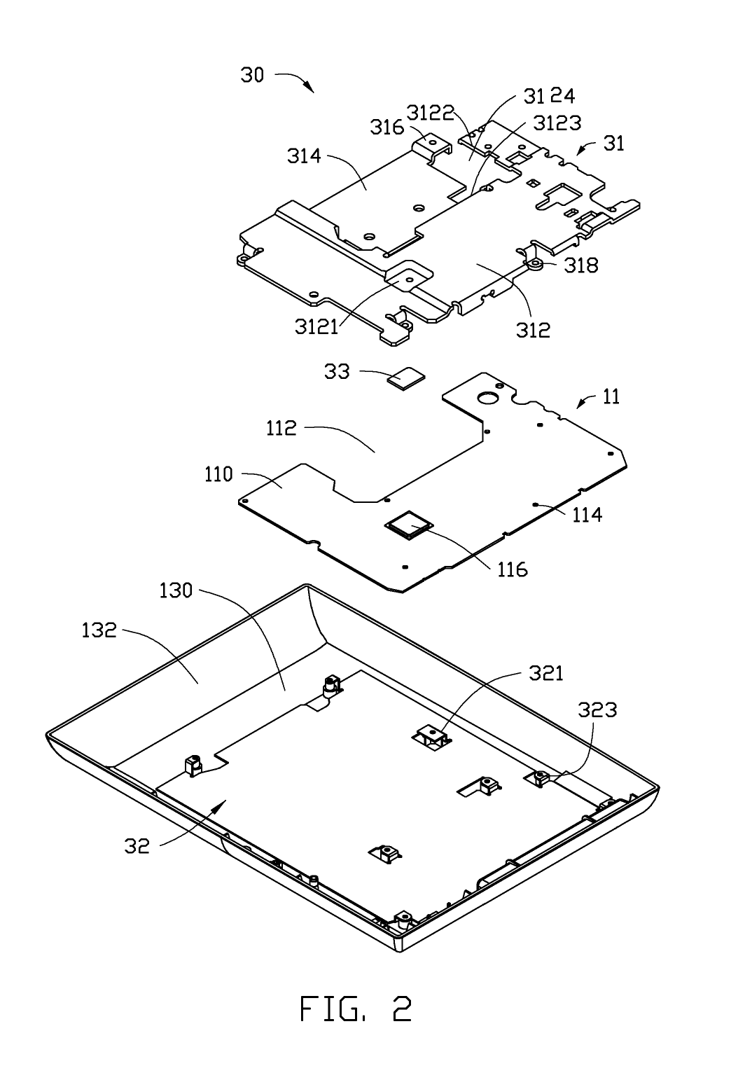

FIGS. 1 and 2 illustrate an embodiment of an electronic device 100. The electronic device 100 includes a base 10, an electronic component 11, a cover 20 rotatably connected to the base 10, and a heat sink mechanism 30. The base 10 includes a top case 12 having a top plate 120 and a bottom case 13 connected to the top case 12. The bottom case 13 includes a bottom plate 130 opposite to the top plate 120 and four sidewalls 132 connecting the bottom plate 130 to the top plate 120. The top case 12 cooperates with the bottom case 13 to define a receiving space (not shown), for receiving the electronic component 11, the heat sink mechanism 30, and other circuit components. The heat sink mechanism 30 dissipates the heating produced by the electronic component 11. The electronic device 100 may be a notebook computer, a disc player, or other electronic devices. In the embodiment, the electronic device 100 is a disc player.

The electronic component 11 includes a first surface 110, a second surface (not shown) opposite to the first surface 110, and a heat-producing component 116. The heat-producing component 116 is positioned on and protrudes out of the first surface 110. The heat-producing component 116 may be an integrated circuit chip, a processor, or other heat-producing components. In the embodiment, the heat-producing component 116 is an integrated circuit chip. The electronic component 11 defines a rectangular opening 112 and a plurality of mounting holes 114. The opening 112 is recessed from a rim of the electronic component 11. The mounting holes 114 are fitted around the edge of the electronic component 11 and are spaced from each other. The inner surface of the mounting holes 114 is an electrical conducting surface. The first surface 110 and the second surface are covered by an insulation layer except where the mounting holes 114 are positioned.

The heat sink mechanism 30 includes a first plate-shaped heat sink component 31 and a second plate-shaped heat sink component 32 engaging with the first heat sink component 31. The first heat sink component 31 and the second heat sink component 32 are arranged on opposite surfaces of the electronic component 11. In the embodiment, the second heat sink component 32 is mounted on the bottom plate 130, the electronic component 11 is arranged on the second heat sink component 32, and the first heat sink component 31 is mounted on a surface of the electronic component 11 opposite to the second heat sink component 32. In the embodiment, the first heat sink component 31 and the second heat sink component 32 are made of aluminum.

The first heat sink component 31 is secured to the first surface 110 of the electronic component 11, and includes a first conducting portion 312, a second conducting portion 314 extending from the first conducting portion 312, a first connecting portion 316 and a plurality of spaced first fixing legs 318.

The first conducting portion 312 defines a substantially U-shaped recess 3124 corresponding to the opening 112 of the electronic component 11. The recess 3124 includes two opposite first sidewalls 3122 and a second sidewall 3123 connecting with the two first sidewalls 3122. The first conducting portion 312 is recessed toward the electronic component 11 to form a concave portion 3121 corresponding to the heat-producing component 116.

The second conducting portion 314 corresponds to and is received in the recess 3124. The second conducting portion 314 connects with the second sidewall 3123 and one of the first sidewalls 3122. The second conducting portion 314 is parallel to and spaced from the first conducting portion 312. When viewed from a top surface of the first conducting portion 312 opposite to the electronic component 11, the second conducting portion 314 is recessed in the first conducting portion 312. When viewed from a bottom surface of the first conducting portion 312 opposite to the top surface, the second conducting portion 314 protrudes out of the first conducting portion 312.

The first connecting portion 316 extends from a side of the second conducting portion 314 adjacent to one of the first edges 3122, and protrudes out of a surface of the second conducting portion 314 opposite to the second heat sink component 32. The first connecting portion 316 in the embodiment is substantially coplanar with the first conducting portion 312.

The first fixing legs 318 are arranged around the edges of the first conducting portion 312 and correspond to the mounting holes 114. The first fixing legs 318 are curved from the edges of the first conducting portion 312 and toward the second heat sink component 32, with the free end extending in a direction parallel to the first conducting portion 312. In the embodiment, the second conducting portion 314, the concave portion 3121, and the first fixing legs 318 are recessed in the same direction relative to the first conducting portion 312. The vertical height of the second conducting portion 314 is substantially equal to the distance between the heat-producing component 116 and a surface of the second heat sink component 32 opposite to the electronic component 11. Furthermore, the distance between the first fixing legs 318 and the first conducting portion 312 is greater than the distance of the concave portion 3121 and the first conducting portion 312.

The second heat sink component 32 is arranged between the bottom plate 130 and the electronic component 11. A second connecting portion 321 and a plurality of spaced second fixing legs 323 are formed on the second heat sink component 32. The second connecting portion 321 corresponds to the first connecting portion 316, for engaging with the first connecting portion 316 to fix the first heat sink component 31 with the second heat sink component 32. The shape of the second fixing legs 323 corresponds to and engages with the first fixing legs 318 respectively. In the embodiment, the area of the second conducting component 32 is larger than the area of the second conducting portion 314.

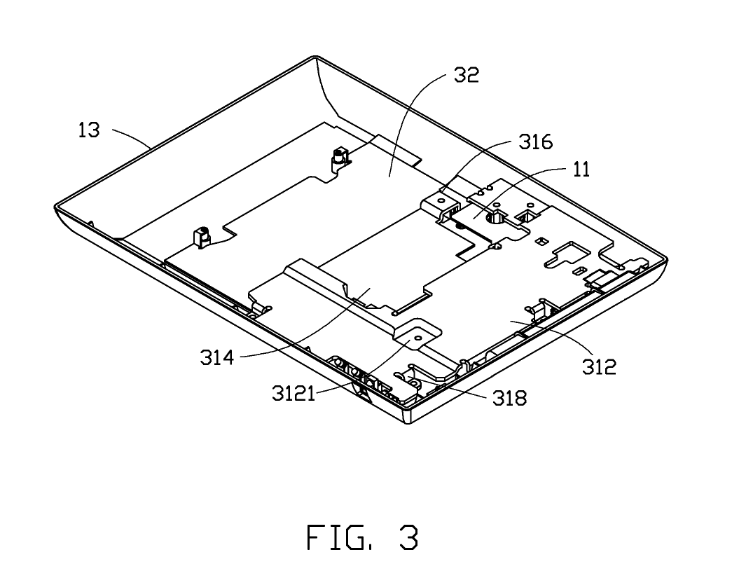

Referring to FIG. 3, in assembly, the second heat sink component 32 is mounted on the bottom plate 130, with the second fixing portion 321 and the second fixing legs 323 toward the top plate 12. The electronic component 11 is mounted on the second heat sink component 32, with the heat-producing component 116 opposite to the second heat sink component 32, and the mounting holes 114 corresponding to the second fixing legs 323. The first heat sink component 31 is mounted on the first surface 110 of the electronic component 11, with the concave portion 3121 corresponding to the heat-producing component 116 and the first fixing legs 318 corresponding to the mounting holes 114. A heat conducting silica gel 33 is glued between the concave portion 3121 and the heat-producing component 116, for transferring the heat from the heat-producing component 116 to the first heat sink component 31. A plurality of fixing members (such as screws, not shown) extend through the first fixing legs 138, the mounting holes 114 and are further secured to the second fixing legs 323, for fixing the first heat sink component 31, the electronic component 11 and the second heat sink component 32 together.

In this state, the first heat sink component 31, the electronic component 11 and the second heat sink component 32 are kept at a predetermined gap with each other. The first conducting portion 312 contacts with the heat-producing component 116. The second heat conducting portion 314 extends through the opening 112 and contacts with the second heat sink component 32.

In use, the heat produced by the heat-producing component 116 is transmitted to the first heat sink component 31 via the heat conducting silica gel 33. The first heat sink component 31 is further transmitted the heat to the second heat sink component 32 via the second heat conducting portion 314, for dissipating the heat and further transmitting out of the electronic device 100. Simultaneously, the electronic component 11 is surrounded by the first and second heat sink components 31, 32. The first fixing legs 318 and the second fixing legs 323 are communicated by the corresponding mounting hole 114. Thus, the heat from the electronic component 11 is also transmitted to the first and second sink components 31, 32. Furthermore, the first and second fixing legs 318, 323 electrically contact the electronic component 11, thus, static electricity of the electronic component 11 is grounded.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
an electronic component, and;
a heat sink mechanism that dissipates heat generated by the electronic component; the heat sink mechanism comprising:
a first heat sink component arranged on a surface of the electronic component, the first heat sink component comprising a first conduction portion and a second conduction portion extending from the first conduction portion, and;
a second heat sink component arranged on a surface opposite to the first heat sink component of the electronic component;
wherein the first conducting portion is secured to the electronic component, and the second conducting portion is secured to the second heat sink component, for dissipating the heat produced by the electronic component away from the electronic device.

2. The electronic device as claimed in claim 1, wherein the first heat sink component defines an open end, the second conducting portion extends from a sidewall of the open end; the electronic component defines an opening corresponding to the open end, the second conducting portion extends through the opening and is secured to the second heat sink component.

3. The electronic device as claimed in claim 1, wherein the electronic component comprises a first surface and a heat-producing component protruding out of the first surface, the first heat sink component is secured to the first surface and comprises a concave portion secured to the heat-producing component.

4. The electronic device as claimed in claim 3, wherein the vertical height of the second conducting portion is substantially equal to the distance between the heat-producing component and a surface of the second heat sink component opposite to the electronic component.

5. The electronic device as claimed in claim 3, wherein the heat sink mechanism comprises a heat conducting silica gel, the heat conducting silica gel is glued between the heat-producing component and the concave portion.

6. The electronic device as claimed in claim 1, wherein the electronic component defines at least one mounting hole, the first heat sink component comprises at least one first fixing leg, the at least one first fixing leg is secured to an end the corresponding mounting hole for allowing the heat from the electronic component to transmit to the first heat sink component.

7. The electronic device as claimed in claim 6, wherein the inner surface of the at least one mounting hole is electrical conducting surface for allowing the static electricity of the electronic component to conduct to ground.

8. The electronic device as claimed in claim 6, wherein the second heat sink component comprises at least one second fixing leg, the at least one second fixing leg is secured to an end of the corresponding mounting hole opposite to the corresponding first fixing leg, for allowing the heat from the electronic component to transmit to the second heat sink component.

9. The electronic device as claimed in claim 8, wherein the at least one first fixing leg protrudes out of the first heat sink component, and the at least one second fixing leg protrudes out of the second heat sink component, for allowing the first heat sink component, the second heat sink component and the main body to keep a predetermined gap with each other.

10. The electronic device as claimed in claim 1, wherein the first and second heat sink components are made of aluminum.

11. A heat sink mechanism for dissipating the heat of an electronic device, the electronic device comprising an electronic component, the heat sink mechanism comprising:
a first heat sink component arranged on a surface of the electronic component, the first heat sink component comprising a first conduction portion and a second conduction portion extending from the first conduction portion, and;
a second heat sink component arranged on a surface opposite to the first heat sink component of the electronic component;
wherein the first conducting portion is secured to the electronic component, and the second conducting portion is secured to the second heat sink component, for dissipating the heat produced by the electronic component away from the electronic device.

12. The heat sink mechanism as claimed in claim 11, wherein the first heat sink component defines an open end, the second conducting portion extends from a sidewall of the open end; the electronic component defines an opening corresponding to the open end, the second conducting portion extends through the opening and is secured to the second heat sink component.

13. The heat sink mechanism as claimed in claim 11, wherein the electronic component comprises a first surface and a heat-producing component protruding out of the first surface, the first heat sink component is secured to the first surface and comprises a concave portion secured to the heat-producing component.

14. The heat sink mechanism as claimed in claim 13, wherein the vertical height of the second conducting portion is substantially equal to the distance between the heat-producing component and a surface of the second heat sink component opposite to the electronic component.

15. The heat sink mechanism as claimed in claim 13, wherein the heat sink mechanism comprises a heat conducting silica gel, the heat conducting silica gel is glued between the heat-producing component and the concave portion.

16. The heat sink mechanism as claimed in claim 11, wherein the electronic component defines at least one mounting hole, the first heat sink component comprises at least one first fixing leg, the at least one first fixing leg is secured to an end the corresponding mounting hole for allowing the heat from the electronic component to transmit to the first heat sink component.

17. The heat sink mechanism as claimed in claim 16, wherein the inner surface of the at least one mounting hole is electrical conducting surface for allowing the static electricity of the electronic component to conduct to ground.

18. The heat sink mechanism as claimed in claim 16, wherein the second heat sink component comprises at least one second fixing leg, the at least one second fixing leg is secured to an end of the corresponding mounting hole opposite to the corresponding first fixing leg, for allowing the heat from the electronic component to transmit to the second heat sink component.

19. The heat sink mechanism as claimed in claim 18, wherein the at least one first fixing leg protrudes out of the first heat sink component, and the at least one second fixing leg protrudes out of the second heat sink component, for allowing the first heat sink component, the second heat sink component and the main body to keep a predetermined gap with each other.

20. The heat sink mechanism as claimed in claim 11, wherein the first and second heat sink components are made of aluminum.
